(19) United States
(12) Patent Application Publication
(10) Pub. No.: US 2025/0293147 A1
(43) Pub. Date: Sep. 18, 2025

(54) PACKAGE SUBSTRATE WITH A RESERVE CAPACITOR

(71) Applicant: QUALCOMM Incorporated, San Diego, CA (US)

(72) Inventors: Hong Bok WE, San Diego, CA (US); Michelle Yejin KIM, Carlsbad, CA (US); Kuiwon KANG, San Diego, CA (US)

(21) Appl. No.: 18/606,541

(22) Filed: Mar. 15, 2024

(51) Int. Cl. H01L 23/522; H01L 23/00; H01L 23/498; H05K 1/02; H05K 1/16

(52) U.S. Cl. CPC H01L 23/5223; H01L 23/49822; H01L 24/32; H05K 1/0231; H05K 1/162; H10D 1/694; H01L 2224/32225; H01L 2924/19041; H01L 2924/30205

(57) ABSTRACT

In an aspect, an IC device may include a base substrate including an embedded component and a first metallization structure. The first metallization structure includes a plurality of first metal layers, a plurality of first dielectric layers, a plurality of first vias configured to couple adjacent metal layers of the plurality of first metal layers through the plurality of first dielectric layers and a reserve capacitor disposed within one of the plurality of first dielectric layers. The reserve capacitor directly coupled between a first contact pad and a second contact pad formed in one of the plurality of first metal layers, and electrically coupled to the embedded component.

### TECHNICAL FIELD

The present disclosure generally relates to semiconductor devices including an integrated circuit (IC) package, and more particularly, but not exclusively, to devices including a printed reserve capacitor in a package substrate and fabrication techniques thereof.

### BACKGROUND

IC technology has achieved great strides in advancing computing power through miniaturization of electronic components. An IC chip or an IC die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a package substrate coupled to one or more IC chips in an IC package, which is different from the semiconductor substrate for forming an IC chip.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth™, and other communications), and the like. As used herein the term “function block” should not be construed to be power or signal lines, traces, conductors, pads, etc. that merely function to transmit an electrical voltage and/or current.

As designs become more complex demands increase on the package substrate design and packaging technology. Many conventional designs utilize embedded components in the package substrate. However, these devices embedded components are subject to electrostatic discharge (ESD) during manufacturing. For example, an embedded capacitor may experience leakage issues due to ESD damage that occurred during substrate manufacturing. Electrical nodes/nets with low net capacitance (higher voltage discharge with lower net capacitance) and deep trench capacitor (DTC) components (e.g., small via connecting metal layer to deep trench layer) are at high risk for ESD damage. To try to avoid this problem in conventional designs, certain net capacitance values need to reassigned to more deep trench capacitor (DTC) rails from other nets which require more capacitance (e.g., design tradeoffs) which can impact power distribution network (PDN) performance in an IC device due to limited number of embedded components available.

Accordingly, there is a need for improved substrate design, IC packaging and methods of manufacturing the same to address the above-noted issues in the conventional technology and other improvements, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a base substrate including an embedded component; and a first metallization structure including: a plurality of first metal layers; a plurality of first dielectric layers; a plurality of first vias configured to couple adjacent metal layers of the plurality of first metal layers through the plurality of first dielectric layers; and a reserve capacitor disposed within one of the plurality of first dielectric layers, directly coupled between a first contact pad and a second contact pad formed in one of the plurality of first metal layers, and electrically coupled to the embedded component.

In an aspect, a method of manufacturing an apparatus comprising a package substrate includes forming a base substrate including an embedded component; and forming a first metallization structure including: forming a plurality of first metal layers; forming a plurality of first dielectric layers; forming a plurality of first vias configured to couple adjacent metal layers of the plurality of first metal layers through the plurality of first dielectric layers; and forming a reserve capacitor disposed within one of the plurality of first dielectric layers, directly coupled between a first contact pad and a second contact pad formed in one of the plurality of first metal layers, and electrically coupled to the embedded component.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 is partial cross-sectional views of apparatus including an integrated circuit (IC) package, according to aspects of the disclosure.

FIGS. 2A-2G illustrate structures at various stages of manufacturing a substrate for an IC package, according to aspects of the disclosure.

FIG. 3 illustrates a method for manufacturing a substrate for an IC package, according to aspects of the disclosure.

FIG. 4 illustrates a mobile device, according to aspects of the disclosure.

FIG. 5 illustrates various electronic devices that may incorporate IC devices being put into the IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, substantially and the like indicate that the examples provided are not intended to be limited to the precise numerical values or geometric shapes and include normal variations due to, manufacturing tolerances and variations, material variations, and other design considerations.

As noted in the foregoing, conventional technologies including conventional packaging technology including embedded components have design limitations due to the embedded components being subject to ESD damage during manufacturing. For example, the embedded components may suffer performance and/or failure issues due to ESD damage that occurred during substrate manufacturing. For example, DTC rails are assigned to different power nets within substrate metal layers and certain nets have smaller net capacitance than the others. Embedded capacitors of those nets with low net capacitance will be discharged with a higher voltage by ESD and are more likely to fail. Additionally, there are a limited number of embedded capacitors due to embedding process limitations in conventional substrates. As discussed above, conventional solutions to try to avoid this problem result in design tradeoffs which can impact performance of IC devices with embedded components. The various aspects disclosed provide improvements including the use of new fabrication processes including adding printed reserve capacitors within substrate (between the outer layer/surface within a dielectric (build-up) layer and the embedded component) in order to prevent ESD damage. As used herein, the term “reserve capacitor” is equivalent to printed reserve capacitor. Additionally, printed reserve capacitors can increase the net capacitance without having to sacrifice the embedded component from other power nets (e.g., relocating other net's DTC rails). Accordingly, the various aspects disclosed provide improved design flexibility with package substrates having a limited number of embedded components.

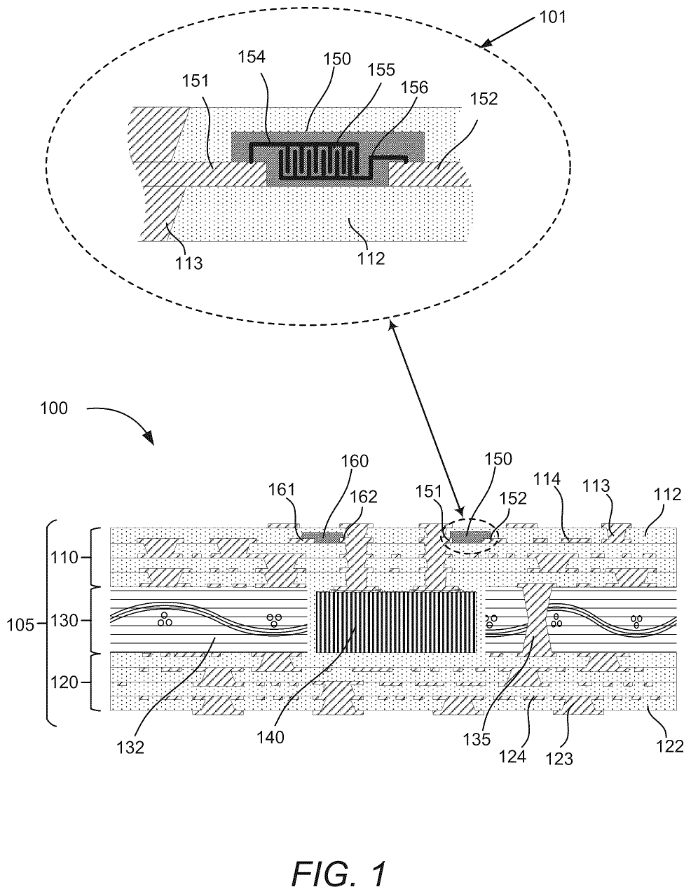

FIG. 1 is a cross-sectional view of an apparatus 100, according to aspects of the disclosure. In some aspects, FIG. 1 is a simplified cross-sectional view of the apparatus 100, and certain details and components of the apparatus 100 may be simplified or omitted in FIG. 1. Portion 101 is detailed in an expanded cross-sectional view of portion 101 of the apparatus 100, and certain details and components of the apparatus 100 may be simplified or omitted in the expanded portion.

In some aspects, as shown in FIG. 1, the apparatus 100 is illustrated as a portion of an IC package and/or a larger apparatus such as a mobile phone, etc. In some aspects, the apparatus 100 includes a base substrate 130 including an embedded component 140 and a first metallization structure 110. The first metallization structure 110 includes a plurality of first metal layers 114, a plurality of first dielectric layers 112, a plurality of first vias 113 configured to couple adjacent metal layers 114 of the plurality of first metal layers 114 through the plurality of first dielectric layers 112, and a reserve capacitor 150 disposed within one of the first plurality of dielectric layers 112. The reserve capacitor 150 is directly coupled between the first contact pad 151 and a second contact pad 152 formed in one of the plurality of first metal layers 114 and electrically coupled to the embedded component 140. In some aspects, the first metallization structure 110 may comprise Ajinomoto build-up film (ABF).

Referring to the detail view of portion 101, the reserve capacitor 150 may include a first electrode 154, a second electrode 156 and a dielectric 155 disposed between the first electrode 154 and the second electrode 156. In some aspects, the first electrode 154 is coupled to the first contact pad 151 and the second electrode 156 is coupled to the second contact pad 152. It will be appreciated that first contact pad 151 and second contact pad 152 may be part of a metal structure used in conventional designs (e.g., a via pad) or may be metal structures specifically added for the reserve capacitor 150 (e.g., an extension off of a given trace, etc.). It will be appreciated that the electrodes in detail portion 101 have been represented in a simplified form case of illustration and explanation. Those skilled in the art will appreciate that the reserve capacitor material has a similar function as a conventional electrode and works as capacitor, but is not literally arranged as illustrated. In some aspects, the first electrode 154 and the second electrode 156 each may include a carbon-based, a non-carbon-based or a hybrid electrode material. For example, the first electrode 154 and the second electrode 156 each may include Graphene Oxide (carbon-based), an Mxene (non-carbon-based), Ruthenium oxide (hybrid). MXenes are a class of two-dimensional inorganic compounds that include atomically thin layers of transition metal carbides, nitrides, or carbonitrides. These material examples are used for printable electrodes which provide for improved discreet components. The dielectric 155 surrounds the electrodes 154 and 156. In some aspects, the dielectric 155 comprises an epoxy based materials, prepreg, ABF, a flame retardant epoxy resin and glass fabric composite (e.g., FR4), Bismaleimide-Triazine (BT) resin, and the like.

In some aspects, as discussed above, the reserve capacitor 150 is configured to provide an electrostatic discharge (ESD) path from the embedded component 140 to provide ESD protection. It will be appreciated that the height of the reserve capacitor 150 is less than a spacing between metal layers of the plurality of first metal layers 114. In some aspects, the reserve capacitor 150 has a height in a range of 5 micrometers (um) to 15 um, a width in a range of 10 um to 100 um, and a length in a range of 50 um to 300 um. However, it will be appreciated that these values may vary based on the desired capacitance, trace thickness, and other design considerations. Accordingly, the various aspects disclosed and claimed should not be construed to be limited to these example values.

Referring to the main figure, in some aspects, a second reserve capacitor 160 may be directly coupled between first contact pad 161 of the second reserve capacitor 160 and a second contact pad 162 of the second reserve capacitor formed in one of the plurality of first metal layers 114 and electrically coupled to the embedded component 140. In the illustrated configuration, the reserve capacitor 150 and second reserve capacitor 160 are both disposed within the same dielectric layer and electrically coupled to different ports of the embedded component 140. It will be appreciated that the various aspects are not limited to this illustrated configuration. For example, only one or more reserve capacitors may be provided. The one or more reserve capacitors may be at different layers than the top dielectric layer, e.g., a layer that would be closest to a die (not illustrated) and different layers from each other. Further, more than one reserve capacitor can be coupled to the same port of the embedded component. Accordingly, it will be appreciated that the example configurations illustrated herein are provided to merely aid in the explanation and are not intended to limit the various aspects disclosed and claimed.

The package substrate 105 further may include: a base substrate 130 including a core 132 including pre-impregnated reinforcement components embedded therein. In some aspects, the base substrate 130 may include at least one plated through hole (PTH) 135 disposed through the core 132 configured to provide an electrical connection to opposite sides of the core 132. In other aspects the base substrate 130 may be coreless. The first metallization structure 110 is disposed on the first side of the base substrate 130. The second metallization structure 120 is disposed on the second side of the base substrate 130.

The second metallization structure 120 may include a plurality of second dielectric layers 122, a plurality of second metal layers 124 and a plurality of second vias 123. The second metallization structure 120 is disposed on a second side of the base substrate 130 opposite the first metallization structure 110. In some aspects, second metallization structure 120 is a conventional buildup with conventional components. In some aspects, the second metallization structure 120 may include one or more reserve capacitors similar to the reserve capacitors described herein. The addition of reserve capacitors in the second metallization structure 120 may be used in conjunction with various design configurations and considerations, such as the DTC pad direction, the use of DTC-EPS (embedded passive substrate) and the like. The second metallization structure 120 may include fiberglass impregnated with resin (prepreg), Ajinomoto build-up film (ABF), or a resin coated copper (RCC) build-up film.

In some aspects, the metal layers and vias of the first metallization structure 110, the second metallization structure 120 and PTH 135 of the base substrate 130 may comprise any high conductive material, such as, copper (Cu), aluminum (AL), silver (Ag), gold (Au) titanium (Ti), nickel (Ni), tin (Sn), lead (Pb), alloys or combinations thereof.

It will be appreciated that the illustrated configurations and descriptions provided herein are merely to aid in the explanation of the various aspects disclosed herein. Accordingly, the forgoing illustrative examples should not be construed to limit the various aspects disclosed and claimed herein.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

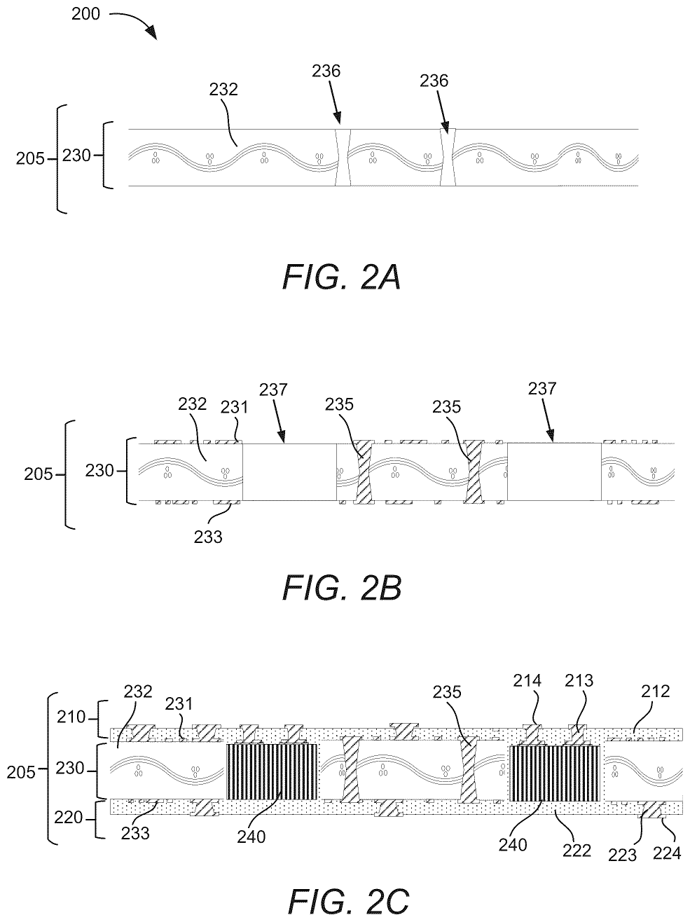

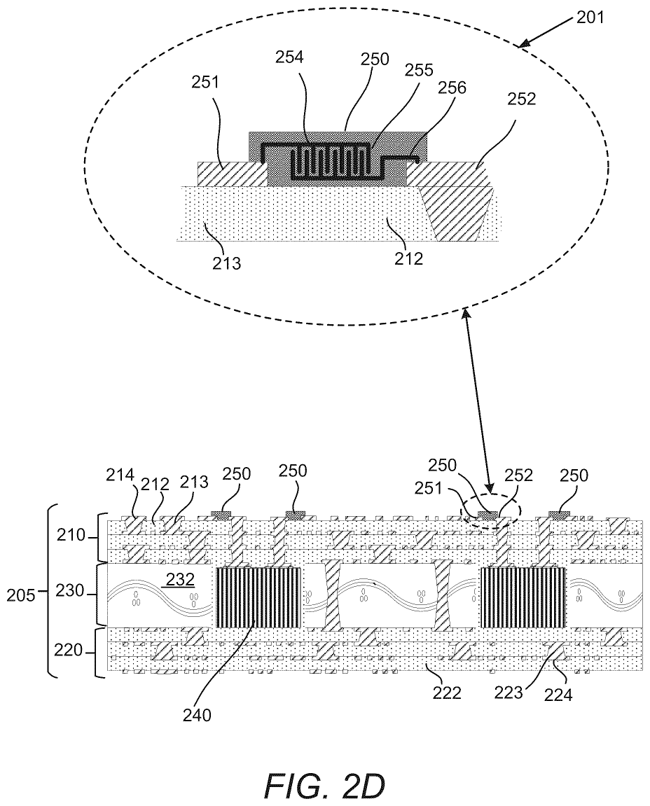

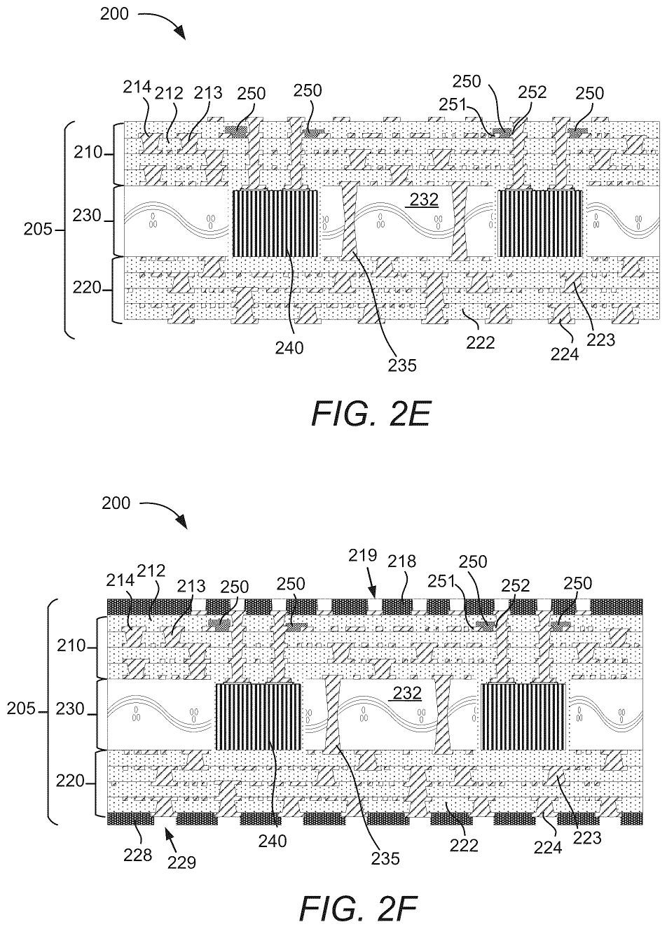

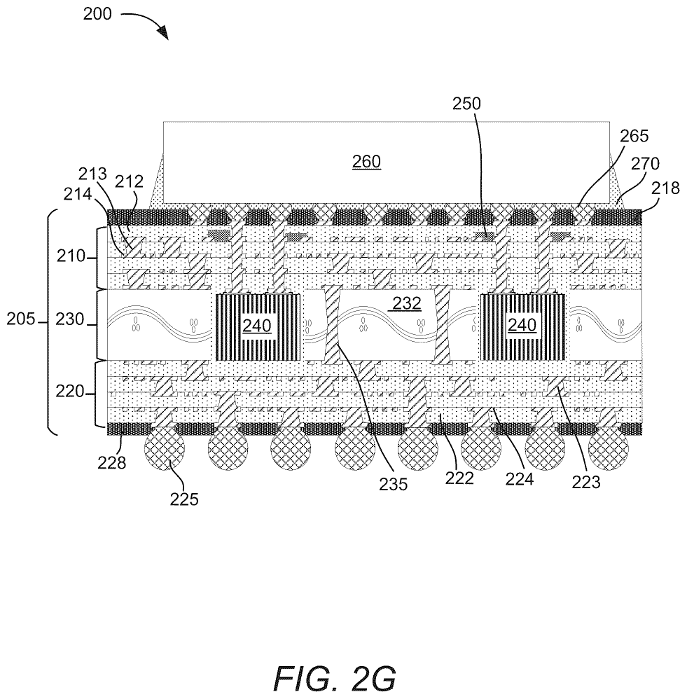

FIGS. 2A-2G illustrate structures at various stages of manufacturing/fabricating an apparatus 200, which is similar to the example apparatus 100 in FIG. 1 as a non-limiting example, according to aspects of the disclosure. Many of the elements illustrated in FIGS. 2A-2G are the same or similar to those of FIG. 1, and therefore detailed description thereof may be omitted.

As shown in FIG. 2A, the fabrication process for apparatus 200 may begin with a package substrate 205 being partially formed including a base substrate 230. At this stage of the fabrication process, one or more cavities 236 are formed in the core 232. The package substrate 205 can be formed using conventional processes (build-up process). To simplify the illustrations and eliminate unnecessary repetition, the following process stages will not provide details of all conventional processing operations. Additionally, since the described elements are similar to corresponding elements described in the foregoing, a detailed description of each will not be provided.

In FIG. 2B, the fabrication process for apparatus 200 may continue with the package substrate 205 being partially formed including the base substrate 230 comprising the core 232, with the cavities filled. At this stage of the fabrication process, one or more plated through holes (PTHs) 235 are formed in the core 232, in the previously formed cavities. Additionally, a first base metal layer 231 and a second base metal layer 233 are deposited on the opposite sides of the core 232, patterned and etched to form the desired metal structures, traces, etc. The PTHs 235 couple portions of the first base metal layer 231 and the second base metal layer 233. Additionally, one or more component cavities 237 are formed in the core 232.

In FIG. 2C, the fabrication process for apparatus 200 may continue with the package substrate 205 being partially formed. The package substrate 205 includes the base substrate 230 comprising the core 232, one or more PTHs 235, the first base metal layer 231, and the second base metal layer 233. At this stage of the fabrication process, one or more embedded components 240 are embedded in the core 232, in the previously formed component cavities. Additionally, the build-up process is started for fabricating the first metallization structure 210 and the second metallization structure 220. The first metallization structure 210 includes a portion of the plurality of first metal layers 214, the plurality of first dielectric layers 212 and the plurality of first vias 213. The second metallization structure 220 includes a portion of the plurality of second metal layers 224, the plurality of second dielectric layers 222 and the plurality of second vias 223.

In FIG. 2D, the fabrication process for apparatus 200 may continue with the package substrate 205 being partially formed. The package substrate 205 includes the base substrate 230 comprising the core 232, one or more PTHs 235, and one or more embedded components 240 embedded in the core 232. The package substrate 205 includes the first metallization structure 210. At this stage of the fabrication process, first metallization structure 210 has additional portions formed of the plurality of first metal layers 214, the plurality of first dielectric layers 212 and the plurality of first vias 213. The second metallization structure 220 also has additional portions formed of the plurality of second metal layers 224, the plurality of second dielectric layers 222 and the plurality of second vias 223. Further, at a given layer, which in some aspects may be a top dielectric layer, one or more reserve capacitors 250 are formed between a first contact pad 251 and a second contact pad 252 that is a metal structure formed as part of a given metal layer.

As illustrated in the detail portion 201, forming the reserve capacitors 250 includes forming a first electrode 254, a second electrode 256, with a dielectric 255 disposed between the first electrode 254 and the second electrode 256. In some aspects, the first electrode 254 is coupled to the first contact pad 251 and the second electrode 256 is coupled to the second contact pad 252. It will be appreciated that first contact pad 251 and second contact pad 252 may be part of a metal structure used in conventional designs (e.g., a via pad) or may be metal structures specifically added for the reserve capacitor 250 (e.g., an extension off of a given trace, etc.). As noted above, the simplified representation of the reserve capacitor 250 is not a physical representation. Further it will be appreciated that the reserve capacitor 250 is formed by a printing process. In some aspects the printing process may comprise an inkjet printing process, Gravure printing, a screen printing process or a three-dimensional (3D) printing process. Accordingly, it will be appreciated that various processes known in the art can be used for fabricating the reserve capacitors 250. Additionally, the printing process can be performed in combination with conventional substrate build-up processes, so conventional techniques can be used to form first metallization structure 210 of the package substrate 205 in combination with the reserve capacitor 250 printing. It will be appreciated that the various aspects including the reserve capacitor 250 printing (e.g., ink jet printing process) can control thickness and position accuracy of the formation of the reserve capacitor 250. In contrast, conventional fabrication processes do not use ink jet printing for substrate manufacturing. In some aspects, the first electrode 254 and the second electrode 256 each may include a carbon-based, a non-carbon-based or a hybrid electrode material. For example, the first electrode and the second electrode each may include Graphene Oxide (carbon-based), an Mxene (non-carbon-based), Ruthenium oxide (hybrid). MXenes are a class of two-dimensional inorganic compounds that include atomically thin layers of transition metal carbides, nitrides, or carbonitrides.

In FIG. 2E, the fabrication process for apparatus 200 may continue with the package substrate 205 being substantially formed. The package substrate 205 includes the base substrate 230 comprising the core 232, one or more PTHs 235, and one or more embedded components 240 embedded in the core 232. The package substrate 205 includes the first metallization structure 210 including the one or more reserve capacitors 250 and the second metallization structure 220. At this stage of the fabrication process, the first metallization structure 210 has additional top portions formed (outer most layers from the base substrate 230) of the plurality of first metal layers 214, the plurality of first dielectric layers 212 and the plurality of first vias 213. The second metallization structure 220 also has additional bottom portions formed (outer most layers from the base substrate 230) of the plurality of second metal layers 224, the plurality of second dielectric layers 222 and the plurality of second vias 223. Further, the top dielectric layer embeds the one or more reserve capacitors 250 and the contacts (e.g., 251 and 252) along with other metal structures in that layer. It will be appreciated that the outer metal layers on both the first metallization structure 210 and the second metallization structure 220 may include pads for forming external connections.

In FIG. 2F, the fabrication process for apparatus 200 may continue with the package substrate 205 being substantially formed. The package substrate 205 includes the base substrate 230 comprising the core 232, one or more PTHs 235, and one or more embedded components 240 embedded in the core 232. The package substrate 205 includes the first metallization structure 210 including the one or more reserve capacitors 250, the plurality of first metal layers 214, the plurality of first dielectric layers 212 and the plurality of first vias 213. The second metallization structure 220 includes the plurality of second metal layers 224, the plurality of second dielectric layers 222 and the plurality of second vias 223. At this stage, a top solder resist (SR) layer 218 is deposited on the top of the first metallization structure 210. A plurality of solder resist openings (SROs) 219 is formed in the SR layer 218 to allow for the die attach process in subsequent processing stages. A bottom solder resist (SR) layer 228 is also deposited on the bottom of the second metallization structure 220. A plurality of solder resist openings (SROs) 229 is formed in the SR layer 228 to allow for the ball attach process in subsequent processing stages.

In FIG. 2G, the fabrication process for apparatus 200 may continue with the package substrate 205 being substantially formed. The package substrate 205 includes the base substrate 230 comprising the core 232, one or more PTHs 235, and one or more embedded components 240 embedded in the core 232. The package substrate 205 further includes the first metallization structure 210 including the one or more reserve capacitors 250, the plurality of first metal layers 214, the plurality of first dielectric layers 212 and the plurality of first vias 213. A top solder resist (SR) layer 218 is deposited on the top of the first metallization structure 210. The second metallization structure 220 includes the plurality of second metal layers 224, the plurality of second dielectric layers 222 and the plurality of second vias 223. A bottom solder resist (SR) layer 228 is deposited on the bottom of the second metallization structure 220. At this stage of the fabrication process a plurality of package connectors 225 (e.g., solder bumps, BGA, copper pillar bumps, pins or any suitable connector technology), coupled to the second metallization structure 220, are formed (e.g., ball-drop on pads of the second metallization structure 220 through the prior SROs or any conventional process). The plurality of package connectors 225 can be configured to couple to an external component, such as a printed circuit board (PCB), additional packages, and the like. Accordingly, it will be appreciated that the package connectors 225 may vary depending on the device design. Additionally, at this stage of the fabrication process a die 260 is disposed on top of the first metallization structure 210 and electrically coupled to the first metallization structure 210 by a plurality of die connectors 265 (e.g., die bumps, solder, pins, pillars, or any suitable connector design) using conventional processes for a given connector technology. In some aspects, a die underfill material 270 may be disposed between the die 260 and the first metallization structure 210 and encapsulate the die connectors 265. In some aspects, the die underfill material 270 comprises an organic material.

It will be appreciated that additional processing can be performed using known techniques to form and attach additional structures (e.g., a mold compound, lid, etc. may be used to encapsulate the die). Additional dies may be coupled to the package substrate or arranged in a stacked structure. Further, the various aspects disclosed may include additional substrates that may be used to interface to a printed circuit board (PCB) or other external device. Accordingly, it will be appreciated that the various aspects disclosed are not limited to the specific configurations illustrated in the accompanying figures.

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

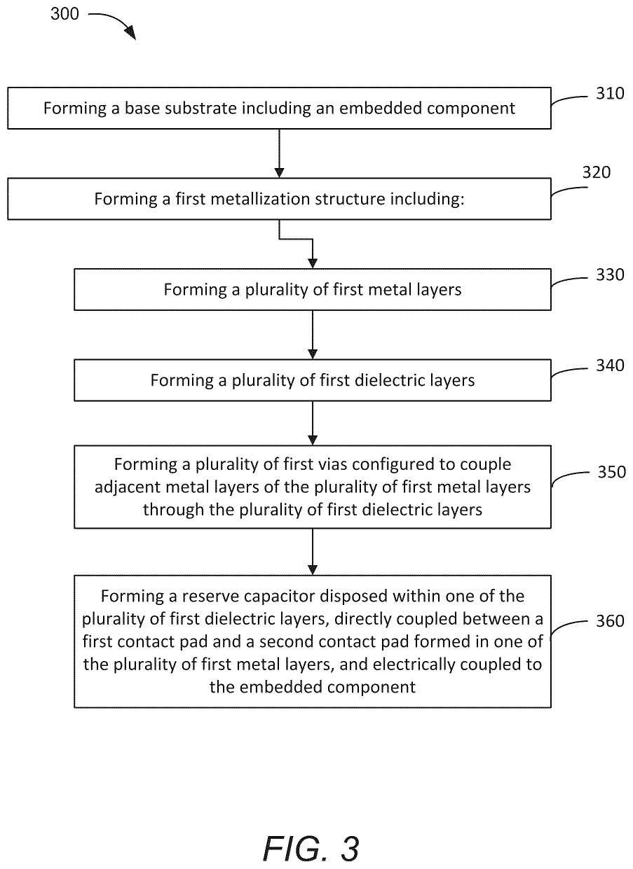

FIG. 3 illustrates a process 300 for manufacturing/fabricating an apparatus comprising a package substrate with reserve capacitors (such as an IC package incorporating the features of any of the example apparatuses 100 or 200), according to aspects of the disclosure. In some aspects, FIGS. 2A-2G may depict the substrate at different stages of manufacturing according to the process 300. It will be appreciated from the foregoing that there are various methods for fabricating devices as disclosed herein.

At operation 310, the process 300 includes forming a base substrate (e.g., base substrate 130 or 230) including an embedded component (e.g., embedded component 140 or 240).

At operation 320, the process 300 includes forming a first metallization structure (e.g., first metallization structure 110 or 210).

At operation 330, the process 300 includes forming a first metallization structure including forming a plurality of first metal layers (e.g., first metal layers 114 or 214).

At operation 340, the process 300 includes forming a first metallization structure including forming a plurality of first dielectric layers (e.g., first dielectric layers 112 or 212).

At operation 350, the process 300 includes forming a first metallization structure including forming a plurality of first vias (e.g., first vias 113 or 213) configured to couple adjacent metal layers of the plurality of first metal layers (e.g., first metal layers 114 or 214) through the plurality of first dielectric layers (e.g., first dielectric layers 112 or 212).

At operation 360, the process 300 includes forming a first metallization structure including forming a reserve capacitor (e.g., reserve capacitor 150 or 250) disposed within one of the plurality of first dielectric layers (e.g., first dielectric layers 112 or 212) and directly coupled between to a first contact pad (e.g., first contact pad 151 or 251) and a second contact pad (e.g., second contact pad 152 or 252) formed in one of the plurality of first metal layers (e.g., first metal layers 114 or 214) and electrically coupled to the embedded component (e.g., embedded component 140 or 240).

It will be appreciated that the foregoing fabrication process was provided merely as a general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

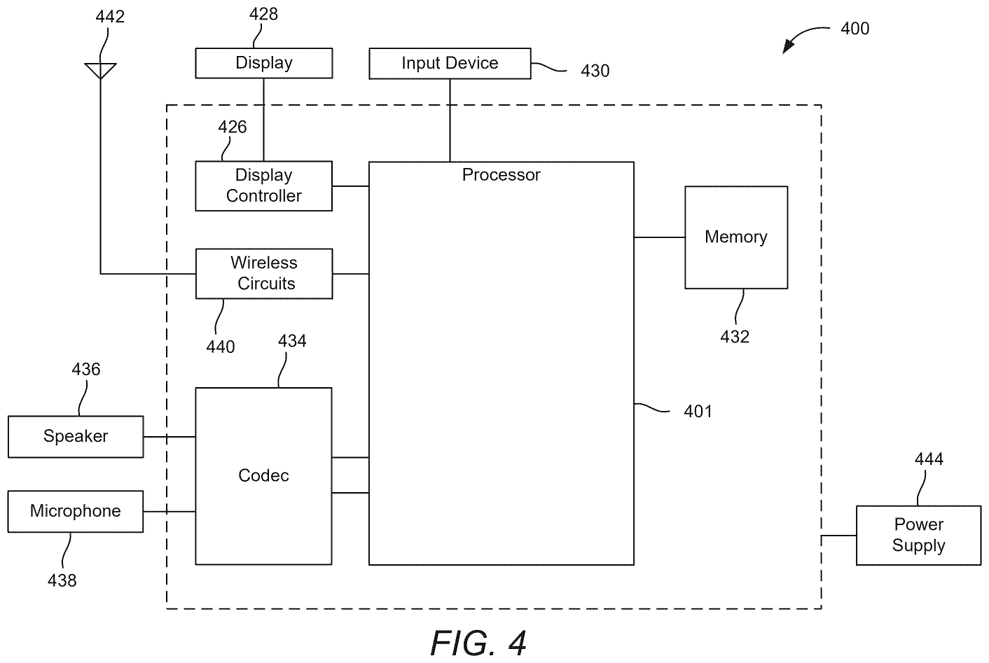

FIG. 4 illustrates a mobile device 400, according to aspects of the disclosure. In some aspects, the mobile device 400 may be implemented by including one or more IC devices including package substrates with printed reserve capacitors as disclosed herein.

In some aspects, mobile device 400 may be configured as a wireless communication device. As shown, mobile device 400 includes processor 401. Processor 401 may be communicatively coupled to memory 432 over a link, which may be a die-to-die or chip-to-chip link. Mobile device 400 also includes display 428 and display controller 426, with display controller 426 coupled to processor 401 and to display 428. The mobile device 400 may include input device 430 (e.g., physical, or virtual keyboard), power supply 444 (e.g., battery), speaker 436, microphone 438, and wireless antenna 442. In some aspects, the power supply 444 may directly or indirectly provide the supply voltage for operating some or all of the components of the mobile device 400.

In some aspects, FIG. 4 may include coder/decoder (CODEC) 434 (e.g., an audio and/or voice CODEC) coupled to processor 401; speaker 436 and microphone 438 coupled to CODEC 434; and wireless circuits 440 (which may include a modem, RF circuitry, filters, etc.) coupled to wireless antenna 442 and to processor 401.

In some aspects, one or more of processor 401 (e.g., SoCs, application processor (AP), central processing unit (CPU), digital signal processor (DSP), etc.), display controller 426, memory 432, CODEC 434, and wireless circuits 440 (e.g., baseband interface) including IC devices that are packaged as IC packages and including package substrates with printed reserve capacitors according to the various aspects described in this disclosure.

It should be noted that although FIG. 4 depicts a mobile device 400, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

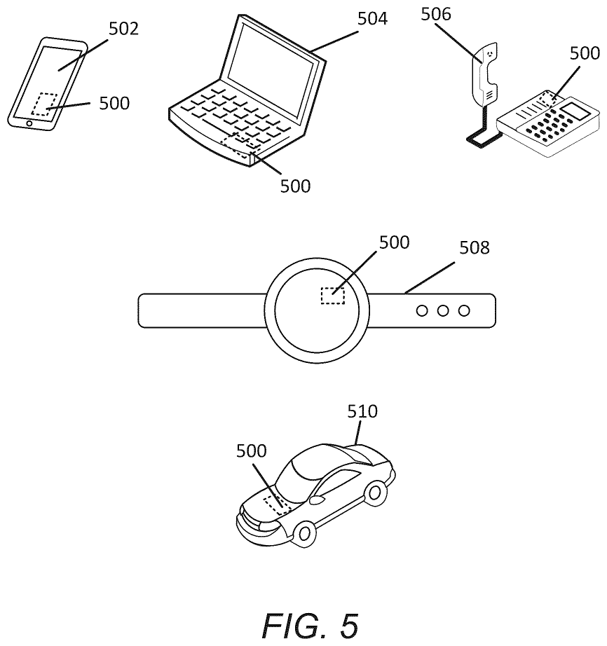

FIG. 5 illustrates various electronic devices that may be integrated with any of the aforementioned devices, semiconductor devices, integrated circuit (IC) packages, integrated circuit (IC) devices, semiconductor devices, integrated circuits, electronic components, interposers, packages, package-on-package (POP), System in Package (SiP), or System on Chip (SoC). For example, a mobile phone device 502, a laptop computer device 504, a fixed location terminal device 506, a wearable device 508, or automotive vehicle 510 may include a semiconductor device 500 (e.g., apparatus 100 and 200 including package substrates 105 and 205, respectively) as described herein. The devices 502, 504, 506 and 508 and the vehicle 510 illustrated in FIG. 5 are merely exemplary. Other apparatuses or devices may also feature the semiconductor device 500 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 5 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1, 2A-2G, and 3-5 may be rearranged and/or combined into a single component, process, feature, or function or incorporated in several components, processes, or functions. Additional elements, components, processes, and/or functions may also be added without departing from the disclosure. In some implementations, FIGS. 1, 2A-2G, and 3-5 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus, comprising a package substrate, the package substrate comprising: a base substrate including an embedded component; and a first metallization structure including: a plurality of first metal layers; a plurality of first dielectric layers; a plurality of first vias configured to couple adjacent metal layers of the plurality of first metal layers through the plurality of first dielectric layers; and a reserve capacitor disposed within one of the plurality of first dielectric layers, directly coupled between a first contact pad and a second contact pad formed in one of the plurality of first metal layers, and electrically coupled to the embedded component.

Clause 2. The apparatus of clause 1, wherein the reserve capacitor comprises a first electrode, a second electrode and a dielectric disposed between the first electrode and the second electrode.

Clause 3. The apparatus of clause 2, wherein the first electrode and the second electrode each comprise a carbon-based, a non-carbon-based or a hybrid electrode material.

Clause 4. The apparatus of any of clauses 2 to 3, wherein the first electrode and the second electrode each comprise Graphene Oxide, an Mxene, or Ruthenium oxide.

Clause 5. The apparatus of any of clauses 1 to 4, wherein the reserve capacitor is configured to provide an electrostatic discharge path from the embedded component.

Clause 6. The apparatus of any of clauses 1 to 5, wherein a height of the reserve capacitor is less than a spacing between metal layers of the plurality of first metal layers.

Clause 7. The apparatus of any of clauses 1 to 6, wherein the reserve capacitor has a height in a range of 5 micrometers (um) to 15 um, a width in a range of 10 um to 100 um, and a length in a range of 50 um to 300 um.

Clause 8. The apparatus of any of clauses 1 to 7, wherein the first metallization structure comprises fiberglass impregnated with resin (prepreg), Ajinomoto build-up film (ABF), or a resin coated copper (RCC) build-up film.

Clause 9. The apparatus of any of clauses 1 to 8, wherein the base substrate comprises: a core including pre-impregnated reinforcement components embedded therein.

Clause 10. The apparatus of clause 9, wherein the base substrate comprises: at least one plated through hole (PTH) disposed through the core configured to provide an electrical connection to opposite sides of the core.

Clause 11. The apparatus of any of clauses 9 to 10, wherein the package substrate further comprises: a second metallization structure comprising a plurality of second dielectric layers, a plurality of second metal layers and a plurality of second vias, wherein the second metallization structure is disposed on a second side of the base substrate opposite the first metallization structure.

Clause 12. The apparatus of clause 11, wherein the second metallization structure comprises: fiberglass impregnated with resin (prepreg); Ajinomoto build-up film (ABF); a resin coated copper (RCC) build-up film; a flame retardant epoxy resin and glass fabric composite; or Bismaleimide-Triazine (BT) resin.

Clause 13. The apparatus of any of clauses 1 to 12, wherein the apparatus further comprises: a die disposed on and electrically coupled to the package substrate.

Clause 14. The apparatus of clause 13, wherein the reserve capacitor is disposed in a top dielectric layer of the plurality of first dielectric layers closest to the die.

Clause 15. The apparatus of any of clauses 1 to 14, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Clause 16. A method of manufacturing an apparatus comprising a package substrate, the method comprising: forming a base substrate including an embedded component; and forming a first metallization structure including: forming a plurality of first metal layers; forming a plurality of first dielectric layers; forming a plurality of first vias configured to couple adjacent metal layers of the plurality of first metal layers through the plurality of first dielectric layers; and forming a reserve capacitor disposed within one of the plurality of first dielectric layers, directly coupled between a first contact pad and a second contact pad formed in one of the plurality of first metal layers, and electrically coupled to the embedded component.

Clause 17. The method of clause 16, wherein forming the reserve capacitor comprises: printing the reserve capacitor comprising a first electrode and a second electrode between the first contact pad and the second contact pad.

Clause 18. The method of clause 17, wherein printing the reserve capacitor comprises at least one of: inkjet printing; screen printing; Gravure printing; or three-dimensional (3D) printing.

Clause 19. The method of any of clauses 17 to 18, wherein the first electrode and the second electrode each comprise a carbon-based, a non-carbon-based or a hybrid electrode material.

Clause 20. The method of any of clauses 16 to 19, further comprising: forming a second metallization structure comprising: forming a plurality of second metal layers; forming a plurality of second dielectric layers; and forming a plurality of second vias configured to couple adjacent metal layers of the plurality of second metal layers through the plurality of second dielectric layers.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus, comprising a package substrate, the package substrate comprising:
a base substrate including an embedded component; and
a first metallization structure including:
a plurality of first metal layers;
a plurality of first dielectric layers;
a plurality of first vias configured to couple adjacent metal layers of the plurality of first metal layers through the plurality of first dielectric layers; and
a reserve capacitor disposed within one of the plurality of first dielectric layers, directly coupled between a first contact pad and a second contact pad formed in one of the plurality of first metal layers, and electrically coupled to the embedded component.

2. The apparatus of claim 1, wherein the reserve capacitor comprises a first electrode, a second electrode and a dielectric disposed between the first electrode and the second electrode.

3. The apparatus of claim 2, wherein the first electrode and the second electrode each comprise a carbon-based, a non-carbon-based or a hybrid electrode material.

4. The apparatus of claim 2, wherein the first electrode and the second electrode each comprise Graphene Oxide, an Mxene, or Ruthenium oxide.

5. The apparatus of claim 1, wherein the reserve capacitor is configured to provide an electrostatic discharge path from the embedded component.

6. The apparatus of claim 1, wherein a height of the reserve capacitor is less than a spacing between metal layers of the plurality of first metal layers.

7. The apparatus of claim 1, wherein the reserve capacitor has a height in a range of 5 micrometers(um) to 15 um, a width in a range of 10 um to 100 um, and a length in a range of 50 um to 300 um.

8. The apparatus of claim 1, wherein the first metallization structure comprises fiberglass impregnated with resin (prepreg), Ajinomoto build-up film (ABF), or a resin coated copper (RCC) build-up film.

9. The apparatus of claim 1, wherein the base substrate comprises:
a core including pre-impregnated reinforcement components embedded therein.

10. The apparatus of claim 9, wherein the base substrate comprises:
at least one plated through hole (PTH) disposed through the core configured to provide an electrical connection to opposite sides of the core.

11. The apparatus of claim 9, wherein the package substrate further comprises:
a second metallization structure comprising a plurality of second dielectric layers, a plurality of second metal layers and a plurality of second vias,
wherein the second metallization structure is disposed on a second side of the base substrate opposite the first metallization structure.

12. The apparatus of claim 11, wherein the second metallization structure comprises:
fiberglass impregnated with resin (prepreg); Ajinomoto build-up film (ABF); a resin coated copper (RCC) build-up film; a flame retardant epoxy resin and glass fabric composite; or Bismaleimide-Triazine (BT) resin.

13. The apparatus of claim 1, wherein the apparatus further comprises:
a die disposed on and electrically coupled to the package substrate.

14. The apparatus of claim 13, wherein the reserve capacitor is disposed in a top dielectric layer of the plurality of first dielectric layers closest to the die.

15. The apparatus of claim 1, wherein the apparatus comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

16. A method of manufacturing an apparatus comprising a package substrate, the method comprising:
forming a base substrate including an embedded component; and
forming a first metallization structure including:
forming a plurality of first metal layers;
forming a plurality of first dielectric layers;
forming a plurality of first vias configured to couple adjacent metal layers of the plurality of first metal layers through the plurality of first dielectric layers; and
forming a reserve capacitor disposed within one of the plurality of first dielectric layers, directly coupled between a first contact pad and a second contact pad formed in one of the plurality of first metal layers, and electrically coupled to the embedded component.

17. The method of claim 16, wherein forming the reserve capacitor comprises:
printing the reserve capacitor comprising a first electrode and a second electrode between the first contact pad and the second contact pad.

18. The method of claim 17, wherein printing the reserve capacitor comprises at least one of:
inkjet printing;
screen printing;
Gravure printing; or
three-dimensional (3D) printing.

19. The method of claim 17, wherein the first electrode and the second electrode each comprise a carbon-based, a non-carbon-based or a hybrid electrode material.

20. The method of claim 16, further comprising:
forming a second metallization structure comprising:
forming a plurality of second metal layers;
forming a plurality of second dielectric layers; and
forming a plurality of second vias configured to couple adjacent metal layers of the plurality of second metal layers through the plurality of second dielectric layers.
